(19) United States
(12) Patent Application Publication
(10) Pub. No.: US 2019/0219532 A1
(43) Pub. Date: Jul. 18, 2019

(54) CONDUCTIVITY SENSOR AND SYSTEM AND METHOD FOR PROCESSING SUBSTRATES INCORPORATING THE SAME

(71) Applicant: NAURA Akrion, Inc., Allentown, PA (US)

(72) Inventors: Ismail Kashkoush, Orefield, PA (US); Jennifer Rieker, Whitehall, PA (US); Dennis Nemeth, Nazareth, PA (US); Robert Benjamin, Hazle Township, PA (US)

(21) Appl. No.: 16/246,778

(22) Filed: Jan. 14, 2019

Related U.S. Application Data
(60) Provisional application No. 62/617,340, filed on Jan. 15, 2018.

(51) Int. Cl. G01N 27/10; G01N 27/07; H01L 21/67

(52) U.S. Cl. CPC G01N 27/10; H01L 21/67086; H01L 21/67253; G01N 27/07

(57) ABSTRACT

A conductivity sensor, a system for processing flat articles that includes a conductivity sensor, and a method of measuring conductivity of a fluid in a semiconductor processing system. The conductivity sensor includes a probe portion and a data analysis portion that are operably coupled together. The probe portion includes a housing extending along a longitudinal axis, a first tube extending through and protruding from the housing, and a second tube extending through and protruding from the housing. A first toroid surrounds the first tube within the cavity of the housing and a second toroid surrounds the second tube within the cavity of the housing. The first toroid may be operably coupled to an alternating current source of the data analysis portion and the second toroid may be operably coupled to a receiver of the data analysis portion.

### CROSS-REFERENCE TO RELATED APPLICATIONS

The present application claims priority to U.S. Provisional Patent Application Ser. No. 62/617,340, filed Jan. 15, 2018, the entirety of which is incorporated herein by reference.

### FIELD

The present invention relates generally to devices and systems that measure conductivity, and more specifically to flow-through type conductivity sensors and systems and methods incorporating the same.

### BACKGROUND

During the processing or fabrication of substrates such as those used in the solar or semiconductor industry, the substrate is subjected to one or more chemical solutions for various purposes including etching, cleaning, or the like. During such processing, it is important to be able to control the concentration of the chemical solution in order to ensure that uniform and repeatable results can be achieved. Furthermore, controlling the concentration of the chemical solution also maximizes the chemical usage by being able to extend the usable bath life of the process, cut down on waste, and reduce the overall cost of ownership. The use of conductivity measurement as a means of controlling the concentration of the chemical solution can be used in systems suitable for a wide variety of cleaning, etching and stripping applications for bare and reclaimed silicon wafers, solar cells, integrated circuit devices, microelectromechanical systems (“MEMS”), and photomasks.

Various forms of conductivity sensors can be used. However, some of these sensors are known to deteriorate and cause metal from the sensor to be introduced into the chemical bath. This contamination of the bath can result in decreased yields and scrapped product, both of which can be very expensive. Accordingly, there exists a need for a conductivity sensor that can accurately measure conductivity of a chemical solution while also preventing metal contamination of the chemical solution.

### SUMMARY

Embodiments of the invention provide conductivity sensors that can accurately measure conductivity of a fluid without contaminating the fluid being measured.

The invention may be directed to a conductivity sensor, a system for processing flat articles that includes a conductivity sensor, and a method of measuring conductivity of a fluid in a semiconductor processing system. The conductivity sensor includes a probe portion and a data analysis portion that are operably coupled together. The probe portion includes a housing extending along a longitudinal axis, a first tube extending through and protruding from the housing, and a second tube extending through and protruding from the housing. A first toroid surrounds the first tube within the cavity of the housing and a second toroid surrounds the second tube within the cavity of the housing. The first toroid may be operably coupled to an alternating current source of the data analysis portion and the second toroid may be operably coupled to a receiver of the data analysis portion.

In one aspect, the invention may be a conductivity sensor for measuring the conductivity of a fluid, the conductivity sensor comprising: a probe portion comprising: a probe housing extending from a first end to a second end along a longitudinal axis and comprising a cavity; a first tube extending through the probe housing and comprising a first fluid flow passageway for conveying the fluid through the probe housing, the first tube having a first portion protruding from the first end of the probe housing, a second portion protruding from the second end of the probe housing, and a third portion located within the cavity of the probe housing; a second tube extending through the probe housing and comprising a second fluid flow passageway for conveying the fluid through the probe housing, the second tube having a first portion protruding from the first end of the probe housing, a second portion protruding from the second end of the probe housing, and a third portion located within the cavity of the probe housing; a first toroid located in the cavity of the probe housing and positioned around an outer surface of the third portion of the first tube; and a second toroid located in the cavity of the probe housing and positioned around an outer surface of the third portion of the second tube.

In another aspect, the invention may be a conductivity sensor for measuring the conductivity of a fluid, the conductivity sensor comprising: a housing extending from a first end to a second end along a longitudinal axis and comprising a cavity; a first tube extending through the housing and comprising a first fluid flow passageway for conveying the fluid through the housing; a second tube extending through the housing and comprising a second fluid flow passageway for conveying the fluid through the housing; a drive toroid located in the cavity of the housing and positioned around an outer surface of the first tube; a sense toroid located in the cavity of the housing and positioned around an outer surface of the second tube; and wherein the first and second fluid flow passageways do not converge within the cavity of the housing.

In yet another aspect, the invention may be a system for processing flat articles comprising: a process tank comprising a process chamber; at least one fluid supply conduit operably coupled to the process tank for introducing a fluid into the process chamber; a recirculation conduit fluidly coupled to the process chamber and configured to circulate the fluid; a conductivity sensor operably coupled to the recirculation conduit and configured to measure conductivity of the fluid circulating through the recirculation conduit, the conductivity sensor comprising: a housing extending from a first end to a second end along a longitudinal axis and comprising a cavity; a first tube fluidly coupled to the recirculation line, the first tube extending through the housing and comprising a first fluid flow passageway for conveying the fluid through the housing; a second tube fluidly coupled to the recirculation line, the second tube extending through the housing and comprising a second fluid flow passageway for conveying the fluid through the housing, wherein the first and second fluid flow passageways do not converge within the cavity of the housing; a first toroid located in the cavity of the housing and positioned around an outer surface of the first tube; and a second toroid located in the cavity of the housing and positioned around an outer surface of the second tube.

In a further aspect, the invention may be a method of measuring conductivity of a fluid in a semiconductor processing system, the method comprising: immersing a substrate in a fluid within a process tank; recirculating the fluid through a recirculation conduit that is operably coupled to the process tank, the fluid flowing through a conductivity sensor that is operably coupled to the recirculation conduit, the recirculation conduit diverging into two flow paths upstream of the conductivity sensor and converging back into a single flow path downstream of the conductivity sensor; and wherein flowing the fluid through the conductivity sensor comprises flowing the fluid through first and second tubes that are coupled to the recirculation conduit, a first toroid being disposed around the first tube and operably coupled to an alternating current source so that the first toroid generates an electromagnetic field that induces an electrical current in the fluid, and a second toroid being disposed around the second tube and operably coupled to a receiver, the second toroid detecting a magnitude of the electrical current in the fluid and transmitting data indicative of the magnitude of the electrical current to the receiver for calculation of a conductivity of the fluid.

In a still further aspect, the invention may be a conductivity sensor for measuring the conductivity of a fluid, the conductivity sensor comprising: a housing comprising a cavity; a first tube defining a first fluid flow passageway through the cavity of the housing; a second tube defining a second fluid flow passageway through the cavity of the housing; a drive toroid located in the cavity of the housing and positioned around an outer surface of the first tube; a sense toroid located in the cavity of the housing and positioned around an outer surface of the second tube; and wherein the first and second fluid flow passageways do not converge within the cavity of the housing.

Further areas of applicability of the present invention will become apparent from the detailed description provided hereinafter. It should be understood that the detailed description and specific examples, while indicating preferred embodiments of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a schematic illustration of a system for processing a flat article according to an embodiment of the present invention;

FIG. 2 is a chart showing a comparison of a failed conductivity probe and a replacement conductivity probe in accordance with prior art conductivity probes;

FIG. 3 is a schematic illustration of a conductivity sensor according to an embodiment of the present invention;

FIG. 4 is a perspective view of a probe portion of the conductivity sensor of FIG. 3;

FIG. 5 is a longitudinal cross-sectional view of the conductivity sensor of FIG. 4; and

FIG. 6 is a schematic illustration of a portion of the system of FIG. 1 that includes a process tank, a recirculation line, and the conductivity sensor of FIGS. 3-5.

All drawings are schematic and not necessarily to scale. Parts given a reference numerical designation in one figure may be considered to be the same parts where they appear in other figures without a numerical designation for brevity unless specifically labeled with a different part number and described herein.

### DETAILED DESCRIPTION

The following description of the preferred embodiment(s) is merely exemplary in nature and is in no way intended to limit the invention, its application, or uses.

The description of illustrative embodiments according to principles of the present invention is intended to be read in connection with the accompanying drawings, which are to be considered part of the entire written description. In the description of the exemplary embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top,” “bottom,” “front” and “rear” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” “secured” and similar refer to a relationship wherein structures are secured or attached to one another either directly or indirectly through intervening structures, as well as both movable or rigid attachments or relationships, unless expressly described otherwise. Moreover, the features and benefits of the invention are described by reference to the exemplary embodiments illustrated herein. Accordingly, the invention expressly should not be limited to such exemplary embodiments, even if indicated as being preferred. The discussion herein describes and illustrates some possible non-limiting combinations of features that may exist alone or in other combinations of features. The scope of the invention is defined by the claims appended hereto.

In some embodiments, the invention described herein is directed to a conductivity sensor that is specifically configured to be coupled to a substrate processing system to measure the conductivity of the fluid (or aqueous solution or chemical solution) being used in the substrate processing system. In other embodiments, the invention described herein is directed to a substrate processing system that incorporates the inventive conductivity sensor therein. In yet other embodiments, the invention described herein is directed to a method of processing substrates that includes flowing a fluid being used during processing through a conductivity sensor having a specific structure as described herein.

In a typical substrate processing operation, the substrate undergoes multiple chemical treatment steps in which the wafer is etched or stripped. In each chemical treatment step, the substrate may be submerged in an aqueous solution (or chemical solution or fluid) or have the aqueous solution sprayed thereon. For example, the substrate may undergo an RCA clean process that includes several steps. The first step is applying standard clean 1 (SC-1) to the substrate, which is a mixture of deionized water (DIW), ammonia water (NH₂), and hydrogen peroxide (H₂O₂), which may remove organic residues and particles from the substrate. This step may also result in the formation of a thin silicon dioxide layer on the surface of the substrate. The second step, which is optional, may include applying an aqueous hydrofluoric acid (HF) to the substrate to remove the thin oxide layer therefrom. The third step is applying standard clean 2 (SC-2) to the substrate, which is a mixture of deionized water, hydrochloric acid (HCl), and hydrogen peroxide (H₂O₂), which may effectively remove the remaining traces of metallic or ionic contaminants from the substrate. The final step may be a rinsing and drying step, which are well-known by those skilled in the art. Thus, each of SC-1, SC-2, and HF may be the aqueous solution or fluid described herein and, as noted above, in each step the substrate may be submerged in the aqueous solution or the aqueous solution may be sprayed onto the substrate. Of course, other fluids or chemical solutions may also be used in the system and the invention is not to be limited by the particular fluid being used unless specifically claimed as such.

For purposes of this invention, it is to be understood that the term substrate, wafer, or flat article is intended to mean any solid substance onto which a layer of another substance is applied and that is used in the solar or semiconductor industries. This includes, without limitation, silicon wafers, glass substrates, fiber optic substrates, fused quartz, fused silica, epitaxial silicon, raw wafers, solar cells, medical devices, disks and heads, flat panel displays, microelectronic masks, and other applications requiring high purity fluids for processing. The terms substrate, wafer, and flat article may be used interchangeably throughout the description herein. Furthermore, it should be understood that the invention is not limited to any particular type of substrate and the methods described herein may be used for the preparation and/or drying of any flat article. For example, the aqueous solution may be an etchant selected from compounds such as nitric acid (HNO₃), hydrofluoric acid (HF), potassium hydroxide (KOH), sodium hydroxide (NaOH), and tetramethylammonium hydroxide (TMAH). The etchant solution may further comprise an amount of deionized water (DIW) as well as other additives, such as isopropyl alcohol (IPA) as well as organic surfactants.

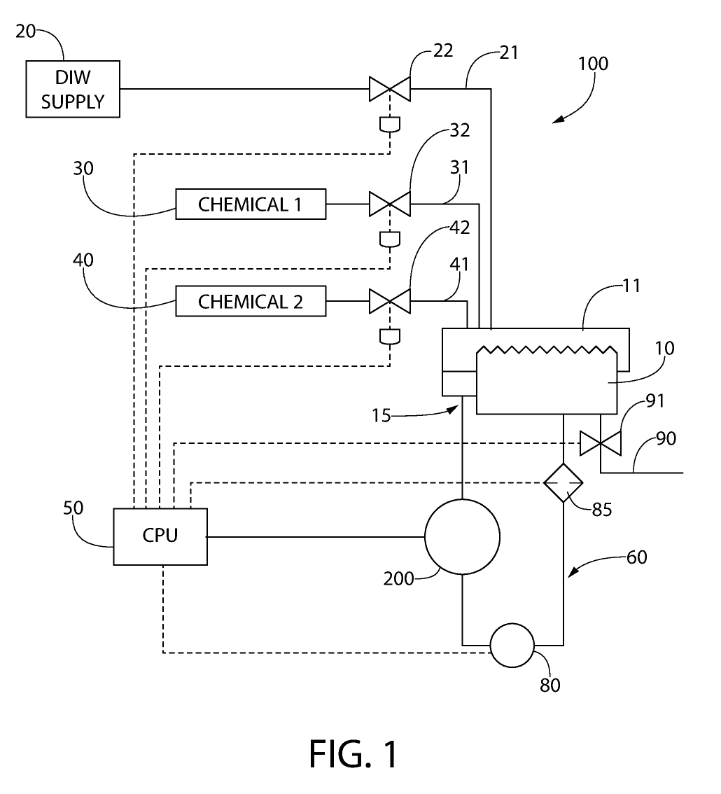

Referring to FIG. 1, a system 100 for processing substrates is illustrated in accordance with an embodiment of the present invention. The invention is not to be limited by the details of the system 100 in all embodiments and various modifications can be made and still fall within the scope of the claimed invention. In some embodiments, the invention is directed to the conductivity sensor and the manner in which it is incorporated into the system 100.

In the exemplified embodiment, the system 100 comprises a closed-loop circulation system 15 comprising a process chamber 10 that houses a bath of a fluid (or aqueous solution or chemical solution) that is used to process a substrate, an overflow chamber 11 (which can be considered a part of the process chamber 10), and a recirculation line or conduit 60. The closed-loop circulation system 15 is configured to circulate a circulation volume of the aqueous solution. In the exemplified embodiment, a conductivity sensor 200, a pump 80, and a heater 85 are positioned along and/or otherwise operably coupled to the recirculation line 60. The recirculation line 60 is fluidly coupled to the process chamber 10 to recirculate the aqueous solution from the process chamber 10 through the recirculation line 60 and back into the process chamber 10. As the aqueous solution flows through the recirculation line 60 the aqueous fluid flows through: (1) the conductivity sensor 200 so that the conductivity of the aqueous solution can be measured: (2) the pump 80; and (3) the heater 85 so that heat can be applied to the aqueous solution. In some embodiments, the heater 85 may be omitted. The system 100 also includes a drain line 90 and a drain valve 91 positioned along the drain line 90 for draining (or bleeding) the aqueous solution from the process chamber 10 to a drainage location as needed.

Although the conductivity sensor 200 is shown being positioned along the recirculation line 60 in the exemplified embodiment, it is possible to place it at other locations while still allowing it to measure the conductivity of the aqueous solution. For example, the conductivity sensor 200 could be positioned directly within the process tank 10 or the overflow chamber 11. However, positioning the conductivity sensor 200 along the recirculation line 60 is the preferred embodiment because positioning the conductivity sensor 200 within the process tank 10 creates a greater likelihood of contamination of the aqueous solution or fluid within the bath. The conductivity sensor 200 is configured to repetitively (at desired time intervals) measure conductivity of the circulation volume of the aqueous solution. According to some embodiments, the conductivity sensor 200 is located within the recirculation line 60. In the exemplified embodiment, the conductivity sensor 200, the pump 80, and the heater 85 are positioned along the recirculation line 60. In other words, the conductivity sensor 200, the pump 80 and the heater 85 are operably coupled to the recirculation line 60).

In the exemplified embodiment, the system 100 also comprises a deionized water (DIW) supply 20 that is operably coupled to the process chamber 10 via a first supply line or conduit 21, a first chemical supply 30 that is operably coupled to the process chamber 10 via a second supply line 31, and a second chemical supply 40 that is operably coupled to the process chamber 10 via a third supply line 41. The first chemical supply 30 may contain an amount of a first chemical and the second chemical supply 40 may contain an amount of a second chemical that may be the same as or different from the first chemical. Each of the first and second chemicals may be any of the chemicals described herein above. A first valve 22 is positioned along the first supply line 21 for controlling the flow of the DIW from the DIW supply 20 to the process chamber 10. A second valve 32 is positioned along the second supply line 31 for controlling the flow of the first chemical from the first chemical supply 30 to the process chamber 10. A third valve 42 is positioned along the third supply line 41 for controlling the flow of the second chemical from the second chemical supply 40 to the process chamber 10.

Although the DIW supply 20 and the two chemical supplies 30, 40 are the only ones shown in the exemplified embodiment, the invention is not to be so limited in all embodiments. The number of chemical supplies can be altered based on the number of chemicals that are needed in the particular aqueous solution or fluid being used during substrate processing. Thus, in certain embodiments only one chemical supply is needed and in other embodiments more than two chemical supplies may be needed.

The system further comprises a controller or central processing unit (CPU) 50. As shown in FIG. 1, each of the first, second, and third valves 22, 32, 42, the conductivity sensor 200, the pump 80, the heater 85, and the drain valve 91 are operably coupled to the controller 50. Thus, the controller 50 controls the opening and closing of the first, second, and third valves 22, 32, 42 and the drain valve 91. The controller 50 also controls the flow of the aqueous solution through the recirculation line 60 by controlling operation of the pump 80. In some embodiments, the aqueous solution may flow through the recirculation line 60 (and hence also through the conductivity sensor 200) at a rate of between 5 and 10 gallons per minute. The controller 50 may also receive measurement data from the conductivity sensor 200. The controller 50 may also control activation of the heater 85 to heat the aqueous solution within the recirculation line 60 in order to maintain the aqueous solution at a reasonably consistent temperature. The controller 50 may include a memory having pre-stored instructions for controlling the various components to which it is operably coupled in accordance with a pre-determined algorithm.

The controller 50 may be programmed with proper algorithms to receive data signals from the conductivity sensor 200, analyze the incoming data signals, compare the values represented by the incoming data signals to stored relationship with etchant concentration and pH value and automatically make appropriate adjustments to the etchant being used to process the substrates by feeding fresh etchant components into the circulation via lines 21, 31, 41 and/or bleeding contaminated/old etchant via the drain line 90 to achieve a predetermined characteristic within the etchant mixture. For example, the controller 50 can store a predetermined conductivity value that has an assigned relationship to the corresponding pH value and aqueous solution concentration. The controller 50 may further comprise a predetermined acceptable operating range for measured conductivity or concentration ratio and/or etchant by-product. More specifically, the controller 50 can be set to store a desired concentration ratio of the KOH, the IPA and the DIW in the etching solution that flows through the closed-loop recirculation system 15.

In one function, the control process repetitively measures the solution conductivity (S/m) of the aqueous solution in the circulation volume, as discussed herein. Such repetitive measurements may be done such that the conductivity sensor 200 is constantly sending data indicative of the conductivity of the fluid to the controller 50 in some embodiments. In other embodiments, the conductivity may only be measured at pre-set intervals (every second, every ten seconds, etc.). Solution conductivity is a measure of available ions in a solution. Therefore, a general relationship between the measured conductivity value of a circulation volume and the concentration of the various chemicals in the aqueous solution may exists. Thus, it may be possible to determine and automatically adjust the concentration of the various parts of the aqueous solution based on the measured conductivity value of the aqueous solution.

In use, the process chamber 10 is filled with the aqueous solution until the aqueous solution overflows the process chamber 10 into the overflow chamber 11. In some embodiments, the process chamber 11 may be fully filled or partially filled. In a non-limiting example, in use the aqueous solution is supplied to the closed-loop circulation system 15 to form mixture having a target concentration ratio and a predetermined volume. The mixture is made to have a specific concentration ratio by opening the valves 22, 32, 42 for a set period of time at a set flow rate to ensure that the proper amount of each chemical is provided in the mixture by the controller 50. The mixture is made to fill the process chamber 10 and overflow into the overflow chamber 11 and into the recirculation line 60.

Upon reaching the overflow chamber 11, the aqueous solution will flow or be pumped via the pump 80 through the recirculation line 60. During flow through the recirculation line 60, the aqueous solution will pass through the conductivity sensor 200 so that the conductivity of the aqueous solution can be taken, as discussed in more detail below. Upon passing the conductivity sensor 200, the aqueous solution will continue to flow through the recirculation line 60 until it is fed back into the process chamber 10. This flow of the aqueous solution through the closed-loop circulation system 15 (i.e., through the process chamber 10 and the recirculation line 60) can be continuous in certain embodiments, or at various time periods as desired. Continuous circulation can be desired in certain embodiments so that continuous measurements of the aqueous solution can be taken by the conductivity sensor 200.

As mentioned above, each of the first, second and third valves 22, 32, 42 and the conductivity sensor 200 may be operably coupled to the controller 50 for communication therebetween. Furthermore, the drain valve 91, the pump 80, and the heater 85 may also be operably coupled to the controller 50. These operable connections can be facilitated via appropriate electric, fiber-optic, cable or other suitable connections, which are illustrated in dashed lines in FIG. 1. The controller 50 is a suitable microprocessor based programmable logic controller, personal computer or the like for process control and preferably includes various input/output ports used to provide connections to the various components of the system 100 that need to be controlled and/or communicated with.

The controller 50 employs the control process of the present invention, as discussed herein. The controller 50 may also comprise sufficient memory to store process recipes, parameters, and other data, such as a predetermined (i.e., target) concentration ratio, a predetermined etch by-product particle count, a predetermined range, flow rates, processing times, processing conditions, and the like. The controller 50 can communicate with any and all of the various components of the system 100 to which it is operably connected in order to automatically adjust process conditions, such, as activating flow through any one of the supply lines 21, 31, 41 either alone or in combination, activating flow through the drain line 90, pump activation, heat application, and filtering.

To etch a substrate, the system 100 may be operated according to an etching method. The etching method includes immersing at least one substrate in an etchant solution within the process chamber 10. The term “immersing” includes substrates that are fully as well as partially immersed in etching solution. The etchant solution may comprise an etchant selected from compounds such as nitric acid (HNO₃), hydrofluoric acid (HF), potassium hydroxide (KOH), sodium hydroxide (NaOH), and tetramethylammonium hydroxide (TMAH). The etchant solution may further comprise an amount of deionized water (DIW) as well as other additives, such as isopropyl alcohol (IPA) as well as organic surfactants. The etchant solution may have a target concentration of etchant that ranges from 0.5 wt. % to 20 wt. % based on the total weight of the etchant solution. In some embodiments, the etchant is present in an amount ranging from 1 wt. % to 10 wt. % based on the total weight of the etchant solution. The target concentration may be selected based on the type of substrate to be etched as well as the type of etching process to be employed. The substrate may be selected from materials such as silicon (Si), silicon dioxide (SiO₂) or silicon nitride (Si₃N₄), or the like.

The process chamber 10 is operably coupled to the recirculation line 60 to form the closed-loop circulation system 15. Once the substrate is immersed, at least three steps are performed. In a first step, a circulation volume of the etchant solution is circulated through the closed-loop circulation system 15. The circulation volume may be a predetermined volume that remains substantially constant during the etching method. The circulation volume of the etchant solution may be circulated through the closed-loop circulation system 15 for a predetermined amount of time at a predetermined flow rate (e.g., 5-10 gallons per minute).

In a second step, the conductivity of the circulation volume of the etchant solution that is circulating through the closed-loop circulation system is repetitively measured by the conductivity sensor 200 for a period of time. Specifically, the conductivity of the circulation volume of the etchant solution that is circulating through the closed-loop circulation system is measured a plurality of times by the conductivity sensor. The plurality of measurements is used to determine an average measured conductivity of the etchant solution. The period of time is a non-zero period of time.

In a third step, the controller 50 uses the control process and compares the average measured conductivity of the circulation volume of the etchant solution with a lower threshold of conductivity that is stored or determined in the controller 50. In some embodiments, the controller 50 may also compare the average measured conductivity of the circulation volume of the etchant solution with an upper threshold of conductivity that is stored or determined in the controller 50.

The ability to control the chemical concentration of etching baths is a critical step for obtaining uniform and repeatable etching results. It also maximizes the chemical usage by being able to extend the usable bath life of the process, cutting down on waste and reducing the overall cost of ownership. The use of conductivity as a means of control can be used in wet stations such as, for example, a system suitable for a wide variety of cleaning, etching and stripping applications for bare & reclaimed silicon wafers, solar cells, IC devices, MEMS and photomasks.

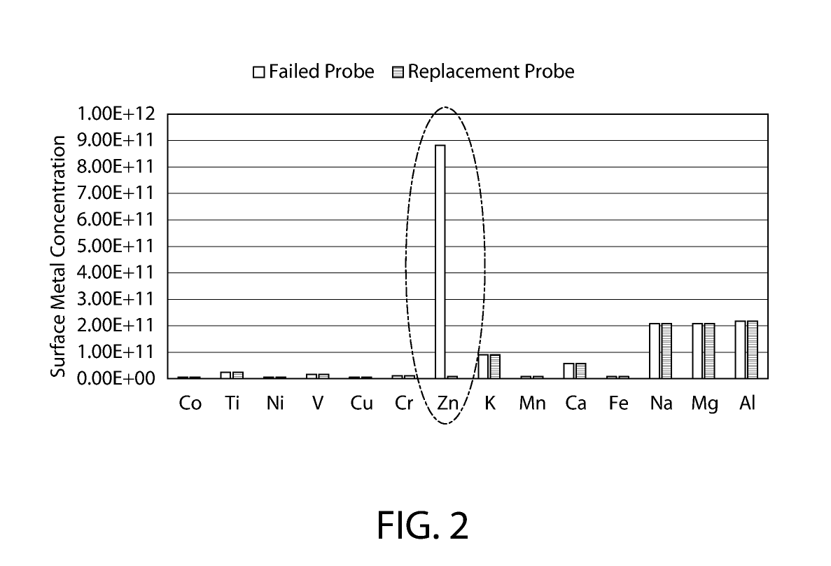

Conductivity measurement sensors are well known in the art and are used to measure the conductivity of a fluid, such as a liquid or a dispersion of solids suspended in a liquid. There are two general types of conductivity sensors, including: (1) electrode conductivity sensors that require the electrodes of the sensor to directly contact the fluid being measured; and (2) toroidal conductivity sensors that operate inductively, meaning that there is no contact between the toroids and the fluid being measured. For semiconductor processing uses, toroidal conductivity sensors are generally preferred because the toroids do not come into contact with the liquid and because they are capable of measuring highly conductive solutions. However, in currently known toroidal conductivity sensors the toroids are coated with perfluoroalkoxy (“PFA”). It is possible for the PFA coating to become breached, which allows the fluid or chemical solution to come into contact with the toroids and contaminate the fluid. In testing done by the inventors of the present application, it was found that when a conductivity probe of the type described above fails, the chemical solution ends up with an increased level of Zinc. Once the conductivity is replaced, the Zinc levels return to the desired levels. See Table 1 below and accompanying FIG. 2, which illustrate this point.

TABLE 1
Metals Data for SC1 Tanks

| | Failed | Replaced |
|---|---|---|
| Metal | Conductivity Probe | Conductivity Probe |
| Co | <6E9 | <6E9 |
| S | 2.928E12 | 1.951E12 |
| Ti | <2.47E10 | <2.47E10 |
| Ni | <6.1E9 | <6.1E9 |
| Cl | 2.373E12 | 2.855E12 |
| V | <1.65E10 | <1.65E10 |
| Cu | <5.9E9 | <5.9E9 |
| Cr | <1.14E10 | <1.14E10 |
| Zn | 8.81E11 | <9.1E9 |
| K | <9.04E10 | <9.04E10 |
| Mn | <9E9 | <9E9 |
| Ca | <5.76E10 | <5.76E10 |
| Fe | <7.3E9 | <7.3E9 |
| Na | <2.074E11 | <2.074E11 |
| Mg | <2.074E11 | <2.074E11 |
| Al | <2.178E11 | <2.178E11 |

The conductivity sensor 200 described herein is of the toroidal type, meaning that it measures conductivity of the fluid in a non-contact manner such that the fluid does not contact the toroids of the conductivity sensor 200. This may be referred to or known in the art as a flow-through conductivity sensor. Toroidal conductivity sensors generally include two toroids, also known as toroidal coils. Generally, a toroid is a structure (e.g., an inductor and/or transformer) that includes a magnetic core made from a ferromagnetic material such as laminated iron, iron powder, ferrite, or the like, around which a conductor such as a wire is wound. Basically, a toroid is a solenoid that is formed into a closed loop (i.e., donut) shape. In toroidal type conductivity sensors, the first toroid or coil is electrically excited by an alternating current source to generate a changing magnetic field. The changing magnetic field induces an electrical current in the fluid being measured. In electrolytic solutions, the mechanism of electrical current transfer is dependent on ions. The magnitude of the induced current is indicative of the conductivity of the fluid. The second toroid or coil detects the magnitude of the induced current in the fluid. Typically, toroidal conductivity sensors are best suited for use in processes where conventional conductivity sensors, such as those with electrodes exposed to the measured solution, would corrode or become foul.

As mentioned above, toroidal and other conductivity probes, can, in some cases, cause elevated metal levels in the chemical baths. Metals contamination is a severe issue that can result in decreased yields and scrapped product. Upon inspection and testing, it has been determined that the root cause in many of these cases is failing conductivity probes. The PFA coating can become breached and allow chemical to come into contact with the metal electrodes and contaminate the baths.

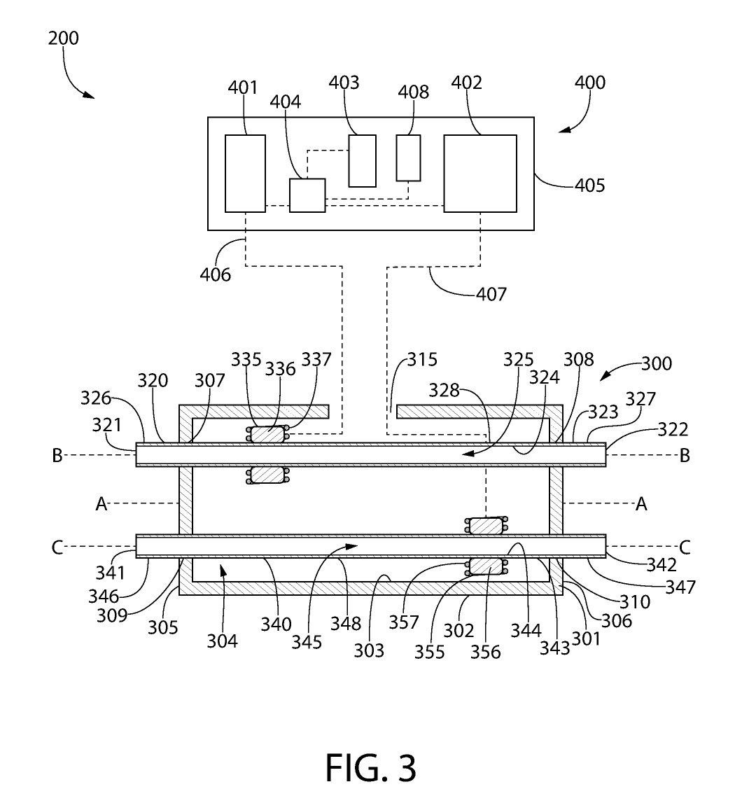

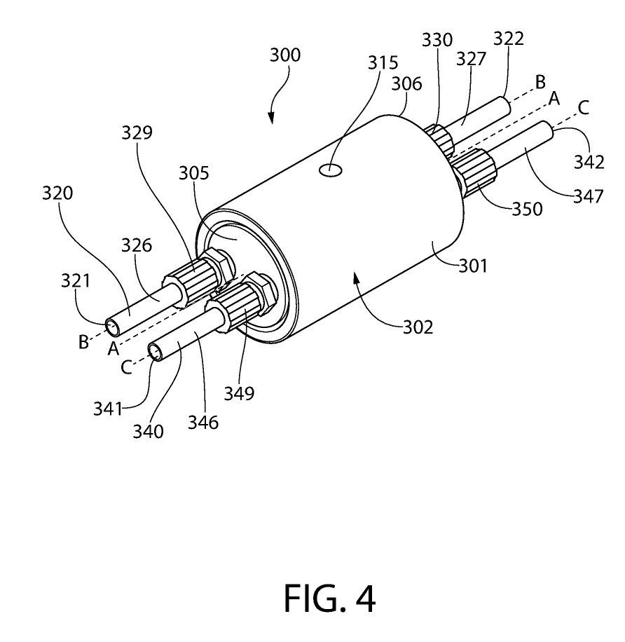

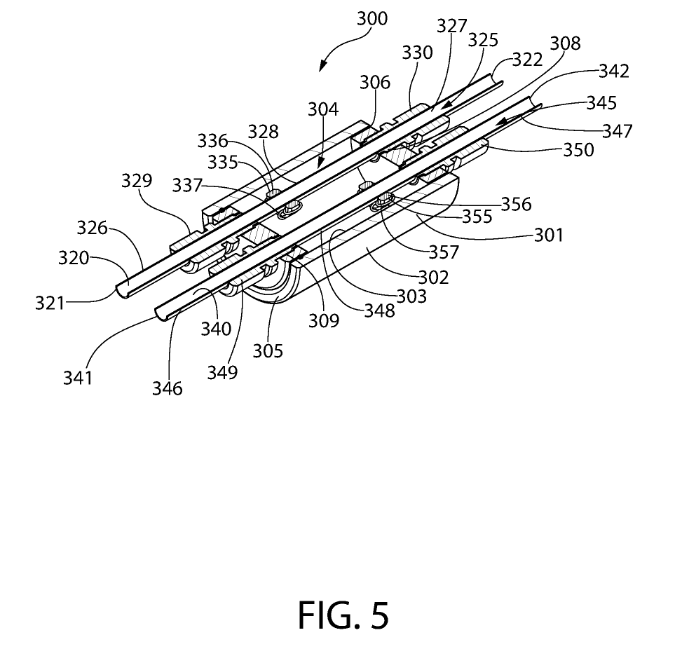

As a solution to these degrading conductivity probes and the resulting contamination of the chemical baths, embodiments of the invention provide a new design for a conductivity probe that utilizes a non-contact measurement. The new design, shown schematically in FIG. 3 and non-schematically in FIGS. 4 and 5, includes two separate flow paths where a toroid is wrapped around each piece of tubing and then encased in a housing. Advantages of embodiments of the invention include: (1) improved material compatibility; (2) added level of protection of the toroids and/or metal electrodes by encasing them and not allowing contact with the process fluid; and (3) decreased likelihood of liquid reaching the toroids and/or metal electrodes even in the event of a breach.

Referring to FIGS. 3-5, the conductivity sensor 200 will be described in greater detail. The conductivity sensor 200 generally comprises a probe portion 300 and a data analysis portion 400 that are operably coupled together via conductive wires or a wireless connection, described in more detail below. The probe portion 300 of the conductivity sensor 200 is the portion that acquires data related to the conductivity of the fluid and the data analysis portion 400 conducts computations based on the acquired data to display or otherwise provide a value of the conductivity of the fluid to an end-user or to the system controller 50 (from FIG. 1). FIGS. 4 and 5 illustrate only the probe portion 300 whereas FIG. 3 illustrates, schematically, the probe and data analysis portions 300, 400.

The probe portion 300 of the conductivity sensor 200 generally comprises a probe housing 301 having an outer surface 302 and an inner surface 303 opposite the outer surface 302. The probe portion 300 comprises a cavity 304 that is defined by the inner surface 303 of the probe housing 301. The probe housing 301 extends from a first end 305 to a second end 306 along a longitudinal axis A-A. In the exemplified embodiment, the probe housing 301 is cylindrical shaped. However, the invention is not to be so limited in all embodiments and the probe housing 301 can take on other shapes in other embodiments. In certain embodiments, the probe housing 301 may be formed from a rigid material to protect the components located within the cavity 304. In one particular embodiment, the probe housing 301 may be formed from polytetrafluoroethylene (PTFE), although other materials including hard plastics such as polypropylene or the like may be used in alternative embodiments. PTFE may be used in pure, virgin form.

The probe portion 300 further comprises a first tube 320 extending from a first end 321 to a second end 322 along a first axis B-B. In the exemplified embodiment, each of the first and second ends 321, 322 of the first tube 320 is flared to facilitate coupling of the first tube 320 to the recirculation line or conduit 60 of the system 100 using a flare fitting or compression fitting. However, the first and second ends 321, 322 of the first tube 320 need not be flared in all embodiments and other types of fittings can be used to ensure a proper coupling is achieved between the recirculation line 60 and the first tube 320. The first tube 320 comprises an outer surface 323 and an inner surface 324 that defines a first fluid flow passageway 325. The first and second ends 321, 322 of the first tube 320 define openings into the first fluid flow passageway 325 such that the first fluid flow passageway 325 extends entirely through the first tube 320 from the first end 321 to the second end 322. The first tube 320 may be formed from PFA or PTFE in some preferred embodiments. In other embodiments, the first tube 320 may be formed from polyvinyl chloride or other electrically non-conductive materials that are capable of transporting the fluid through the first fluid flow passageway 325 without deteriorating the material of the first tube 320. The material of the first tube 320 should be selected to ensure that it will not contaminate the fluid flowing therethrough.

The first tube 320 extends through a first opening 307 in the first end 305 of the probe housing 301 and through a second opening 308 in the second end 306 of the probe housing 301. The first tube 320 has a length, measured from the first end 321 of the first tube 320 to the second end 322 of the first tube 320, that is greater than a length of the probe housing 301 measured from the first end 305 of the probe housing 301 to the second end 306 of the probe housing. In some embodiments, the length of the first tube 320 may be between 7 inches and 9 inches, and more specifically approximately 8 inches. Thus, because the first tube 320 has a greater length than the probe housing 301, the first tube 320 comprises a first portion 326 that protrudes from the first end 305 of the probe housing 301, a second portion 327 that protrudes from the second end 306 of the probe housing 301, and a third portion 328 located within the cavity 304 of the probe housing 301. Of course, in other embodiments no portions of the first tube 320 may protrude from the first and second ends 305, 306 of the probe housing 301. Stated another way, in some embodiments the first tube 320 defines the first fluid flow passageway 325 within and through the cavity 304 of the probe housing 301 regardless of whether parts of the first tube 320 extend or otherwise protrude from the ends of the probe housing 301.

In certain embodiments, the first tube 320 is securely coupled to the probe housing 301 so that the first tube 320 is prevented from moving axially relative to the probe housing 301. However, in other embodiments it may be possible to move the first tube 320 axially relative to the probe housing 301 even while the first tube 320 is coupled to the probe housing 301. In either case, the first and second portions 326, 327 of the first tube 320 should extend or otherwise protrude from the first and second ends 305, 306 of the probe housing 301, respectively, while the third portion 328 of the first tube 320 extends through the cavity 304 of the probe housing 301. In the exemplified embodiment, the first tube 320 is coupled to the probe housing 301 via first and second compression seals 329, 330. The first and second compression seals 329, 330 seal the first and second openings 307, 308 in the probe housing 301 to prevent fluids from passing through the first and second openings 307, 308 and into the cavity 304. Of course, other mechanisms can be used to seal the first and second openings 307, 308 and/or couple the first tube 320 to the probe housing 301. In some embodiments, the first and second compression seals 329, 330 may not be needed and the first tube 320 may seal the first and second openings 307, 308 by itself. The first and second compression seals 329, 330 are not shown in FIG. 3, but they are depicted in FIGS. 4 and 5.

The probe portion 300 further comprises a second tube 340 extending from a first end 341 to a second end 342 along a second axis C-C. In the exemplified embodiment, each of the first and second ends 341, 342 of the second tube 340 is flared to facilitate coupling of the second tube 340 to the recirculation line or conduit 60 of the system 100 using a flare fitting or compression fitting. However, the first and second ends 341, 342 of the second tube 320 need not be flared in all embodiments and other types of fittings can be used to ensure a proper coupling is achieved between the recirculation line 60 and the second tube 340. The second tube 340 comprises an outer surface 343 and an inner surface 344 that defines a second fluid flow passageway 345. The first and second ends 341, 342 of the second tube 3440 define openings into the second fluid flow passageway 345 such that the second fluid flow passageway 345 extends entirely through the second tube 340 from the first end 341 to the second end 342. The second tube 340 may be formed from PFA or PTFE in some preferred embodiments. In other embodiments, the second tube 340 may be formed from polyvinyl chloride or other electrically non-conductive materials that are capable of transporting the fluid through the second fluid flow passageway 345 without deteriorating the material of the second tube 340. The material of the second tube 340 should be selected to ensure that it will not contaminate the fluid flowing therethrough.

The second tube 340 extends through a third opening 309 in the first end 305 of the probe housing 301 and through a fourth opening 310 in the second end 306 of the probe housing 301. The second tube 340 has a length, measured from the first end 341 of the second tube 340 to the second end 322 of the second tube 340, that is greater than the length of the probe housing 301 measured from the first end 305 of the probe housing 301 to the second end 306 of the probe housing. In some embodiments, the length of the second tube 340 may be the same as the length of the first tube 320, which as noted above is between 7 inches and 9 inches, and more specifically approximately 8 inches. Thus, because the second tube 340 has a greater length than the probe housing 301, the second tube 340 comprises a first portion 346 that extends from the first end 305 of the probe housing 301, a second portion 347 that extends from the second end 306 of the probe housing 301, and a third portion 348 located within the cavity 304 of the probe housing 301. Of course, in other embodiments no portions of the first tube 320 may protrude from the first and second ends 305, 306 of the probe housing 301. Stated another way, in some embodiments the second tube 340 defines the second fluid flow passageway 345 within and through the cavity 304 of the probe housing 301 regardless of whether parts of the second tube 340 extend or otherwise protrude from the ends of the probe housing 301.

In certain embodiments, the second tube 340 is securely coupled to the probe housing 301 so that the second tube 340 is prevented from moving axially relative to the probe housing 301. However, in other embodiments it may be possible to move the second tube 340 axially relative to the probe housing 301 even while the second tube 340 is coupled to the probe housing 301. In either case, in the exemplified embodiment the first and second portions 346, 347 of the second tube 340 extend or otherwise protrude from the first and second ends 305, 306 of the probe housing 301, respectively, while the third portion 348 of the second tube 340 extends through the cavity 304 of the probe housing 301. In the exemplified embodiment, the second tube 340 is coupled to the probe housing 301 via third and fourth compression seals 349, 350. The third and fourth compression seals 349, 350 seal the third and fourth openings 309, 310 in the probe housing 301 to prevent fluids from passing through the third and fourth openings 309, 310 and into the cavity 304. Of course, other mechanisms can be used to seal the third and fourth openings 309, 310 and/or couple the second tube 340 to the probe housing 301. In some embodiments, the third and fourth compression seals 349, 350 may not be needed and the second tube 340 may seal the third and fourth openings 309, 310 by itself. The third and fourth compression seals 349, 350 are not shown in FIG. 3, but they are depicted in FIGS. 4 and 5.

In some examples, the first and second tubes 320, 340 are ½″, ¾″, or 1″ diameter tubes and the probe housing 301 slides over the first and second tubes 320, 340. In some embodiments, the tubes 320, 340 may have a wall thickness between 1 mm and 2 mm. In some embodiments, the tubes 320, 340 may be integrally formed with probe housing 301. For example, the first and second tubes 320, 340 as separate components from the probe housing 301 may be omitted and the probe housing 301 may be formed so that the first and second fluid flow passageways 325, 345 are created as an integral part of the probe housing 301. In other embodiments, the tubes 320, 340 may be separately formed from the probe housing 301 and later coupled thereto as described herein.

The probe portion 300 of the conductivity sensor 200 further comprises a first toroid 335 disposed around the first tube 320 and a second toroid 355 disposed around the second tube 340. The first toroid 335 comprises a first core 336 and a first conductive wire 337 wound around the first core 336. The first core 336 is ring-like or donut-shaped so that the first toroid 335 can be disposed around the outer surface 323 of the first tube 320 with the first tube 320 passing through the opening in the first core 336. The second toroid 355 comprises a second core 356 and a second conductive wire 357 wound around the second core 356. The second core 356 is ring-like or donut-shaped so that the second toroid 355 can be disposed around the outer surface 343 of the second tube 340 with the second tube 340 passing through the opening in the second core 356. As described in further detail below the first toroid 335 may be configured as a drive coil and the second toroid 355 may be configured as a sense coil based on their operable coupling to components of the data analysis portion 400 of the conductivity sensor 200.

In the exemplified embodiment, the first and second toroids 335, 345 are axially spaced apart from one another within the cavity 304 of the probe housing 301. Thus, the first toroid 335 is closer to the first end 305 of the probe housing 301 than the second toroid 355 and the second toroid 355 is closer to the second end 306 of the probe housing 301 than the first toroid 335. Furthermore, in the exemplified embodiment the first toroid 335 is the only toroid coupled to the first tube 320 and the second toroid 355 is the only toroid coupled to the second tube 340. Thus, there is exactly one toroid (the first toroid 335) disposed around the first tube 320 and there is exactly one toroid (the second toroid 355) disposed around the second tube 340.

As mentioned above, the probe housing 301 extends along a longitudinal axis A-A, the first tube 320 extends along the first axis B-B, and the second tube 340 extends along the second axis C-C. In the exemplified embodiment, the longitudinal axis A-A of the probe housing 301, the first axis B-B of the first tube 320, and the second axis C-C of the second tube 340 are parallel to one another. Furthermore, as seen in the figures and discussed above, the first and second tubes 320, 340 each extend the entire way through the cavity 304 such that the first and second tubes 320, 340 both extend or protrude from each of the first and second ends 305, 306 of the probe housing 301. Thus, the first and second tubes 320, 340 form two separate fluid passageways through the probe housing 301. In the exemplified embodiment, the first and second fluid flow passageways 325, 345 do not converge within the cavity 304 of the probe housing 301. This may be possible regardless of whether the first and second tubes 320, 340 protrude from the first and second ends 305, 306 of the probe housing 301.

Thus, at least within and through the entirety of the cavity 304 of the probe housing 301, the first and second fluid flow passageways 325, 345 are two separate and distinct passageways. Thus, within the cavity 304, the fluid in the first fluid flow passageway 325 will not mix with the fluid in the second fluid flow passageway 345. The same fluid is flowing through each of the first and second fluid flow passageways 325, 345 because the fluid does converge within the recirculation line 60, but such convergence does not occur within the cavity 304 of the probe housing 301. This is important because it makes a leak situation within the cavity 304 of the probe housing 301, where the first and second toroids 335, 355 are located, very unlikely. Specifically, because the first and second fluid flow passageways 325, 345 flow in a linear manner through the cavity 304 of the probe housing 301, there are no turns or the like required. Thus, the first and second fluid flow passageways 325, 345 can each be formed by a single, unitary, monolithic tube (i.e., the first and second tubes 320, 340). The first tube 320 is a monolithic and integrally formed singular tube and the second tube 340 is a monolithic and integrally formed singular tube that is distinct from the first tube 320. Because there are no couplers or the like needed to form the fluid flow passageways 325, 345, which would be required if the first and second fluid flow passageways 325, 345 were to converge within the cavity 304 of the probe housing 301, there is an extremely low likelihood that the fluid will leak out of the first and/or second tubes 320, 340 and into the cavity 304 of the probe housing 301. This ensures that the first and second toroids 335, 355 will not come into contact with the fluid and therefore will not contaminate the fluid.

Moreover, because the fluid flows only through the first and second tubes 320, 340, the probe housing 301 never needs to be immersed in the fluid. Specifically, the first and second tubes 320, 340 are simply hooked up to the recirculation line 60 so that the fluid can flow through the first and second passageways 325, 345. Thus, because the probe housing 301 is not immersed in the fluid, the fluid will never have an opportunity to flow into the cavity 304 through the probe housing 301 itself. The only chance that the fluid would flow into the cavity 304 would be if a hole, crack, or other deterioration occurs within the the third portion 328, 348 of one of the first and second tubes 320, 340. And even then, the fluid will remain in the cavity 304 of the probe housing 301 and will not enter back into the first and second tubes 320, 340, and therefore will not contaminate the fluid in the bath within the process tank 10.

Referring to FIG. 3, as mentioned above the conductivity sensor 200 comprises a data analysis portion 400 in addition to the probe portion 300. The data analysis portion 400 is operably coupled to the probe portion 300 as described herein. Specifically, the data analysis portion 400 comprises an alternating current source 401, a receiver 402, a display device 403, a power source 408, and a controller 404. The data analysis portion 400 further comprises a second housing 405 that houses each of the alternating current source 401, the receiver 402, the display device 403, the power source 408, and the controller 404.

In the exemplified embodiment, the power source 408 may be batteries or the like that are located within the second housing 405. Furthermore, in the exemplified embodiment the power source 408 is directly coupled to only the controller 404, which then provides power to each of the other components of the data analysis portion 400. In other embodiments, the power source 408 may be directly coupled to each of the alternating current source 401, the receiver 402, the display device 403, and the controller 404. In alternative embodiments, the power source 408 may be located outside of the second housing 405. For example, the power source may be a wall outlet and the data analysis portion 400 may have a plug for operable coupling to the wall outlet. The exact structure and details of the power source 408 are not to be limiting of the present invention and any power source may be used.

Each of the alternating current source 401, the receiver 402, and the display device 403 may be operably coupled to the controller 404. The first toroid 335 is operably coupled to the alternating current source 401. When the alternating current source 401 is activated, it causes the first toroid 335 to generate a changing magnetic (i.e., electromagnetic) field. Thus, the first toroid 335 may be considered a drive toroid or a drive coil. The second toroid 355 is operably coupled to the receiver 402 to transmit data indicative of the current in the fluid to the receiver 402. Thus, the second toroid 355 may be considered a sense (or receive) toroid or a sense (or receive) coil. The coupling between the first toroid 335 and the alternating current source 401 and between the second toroid 355 and the receiver 402 may be achieved via conductive wires 406, 407 as shown in the exemplified embodiment or using other techniques known in the art.

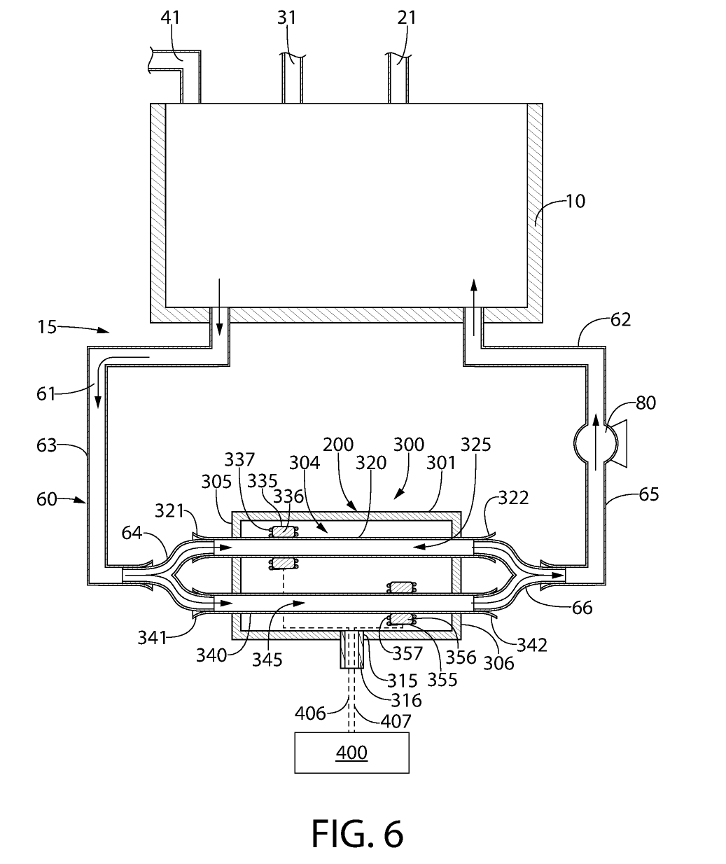

In the exemplified embodiment, the conductive wires 406, 407 extend through a fifth opening 315 in the probe housing 301. The fifth opening 315 should be sealed in some embodiments using a seal member 316 (see FIG. 6) to ensure that fluids cannot enter into the cavity 304 of the probe housing 301 via the fifth opening 315. The seal member 316 would include openings/passageways for the wires 406, 407 but would prevent liquid from passing through the fifth opening 315 and into the cavity 304 of the probe housing 301. However, because the probe housing 301 is not immersed in any fluid baths as discussed above, there is a low likelihood of any fluid passing into the cavity 304 through the fifth opening 315 even without such a seal and thus the seal 316 may be omitted in some embodiments. Although the coupling between the components of the probe portion 300 and the components of the data analysis portion 400 are shown generically in FIG. 3, in some embodiments the probe portion 300 and the analysis portion 400 may comprise mating male and female plug portions that when mated operably couple the first and second toroids 335, 355 to the alternating current generator 401 and the receiver 402, respectively.

FIG. 6 illustrates in more detail, and schematically, the coupling of the conductivity sensor 200 to the recirculation conduit 60. The first and second tubes 320, 340 of the conductivity sensor 200 are operably coupled to the recirculation line 60 so that the fluid flowing through the recirculation line 60 also flows through the first and second tubes 320, 340. Thus, as described above, the probe housing 301 is never immersed in the fluid and preferably never comes into contact with the fluid. As a result, the fluid is much less likely to come into contact with the first and second toroids 335, 355, which prevents contamination of the fluid as described above. In the exemplified embodiment, the probe housing 301 is hermetically sealed so that fluids cannot flow into the cavity 304 of the probe housing 301 other than through the first and second tubes 320, 340 that extend into the probe housing 301.

The recirculation conduit 60 comprises a first portion 61 extending from the process tank 10 to the first ends 321, 341 of the first and second tubes 320, 340 and a second portion 62 extending from the process tank 10 to the second ends 323, 342 of the first and second tubes 320, 340.

More specifically, the first portion 61 comprises a first conduit 63 and a first connector 64 for coupling the first conduit 63 to the first ends 321, 341 of each of the first and second tubes 320, 340. The first connector 64 may be a compression fitting, a flare fitting, or the like so long as it fluidly couples the first conduit 63 of the first portion 61 of the recirculation line 60 to the first ends 321, 341 of the first and second tubes 320, 340. In the exemplified embodiment, the first connector 64 is a Y-coupler such that on one end it has a single opening for coupling to the first conduit 63 and on the other end is has two openings for coupling to the first ends 321, 341 of each of the first and second tubes 320, 340. Thus, the first portion 61 of the recirculation line 60, which includes the first conduit 63 and the first connector 64, diverges from a single pathway into two pathways upstream of the first ends 321, 341 of the first and second tubes 320, 340 in a direction of the flow of the fluid through the recirculation line 60. Flare fittings, compression fittings, or the like may be used to couple the connector 64 to the first conduit 63 and to the first and second tubes 320, 340.

Furthermore, the second portion 62 comprises a second conduit 65 and a second connector 66 for coupling the second conduit 65 to the second ends 322, 342 of each of the first and second tubes 320, 340. The second connector 66 may be a compression fitting, a flare fitting, or the like so long as it fluidly couples the second conduit 65 of the second portion 62 of the recirculation line 60 to the second ends 322, 342 of the first and second tubes 320, 340. In the exemplified embodiment, the second connector 66 is a Y-coupler such that on one end it has a single opening for coupling to the second conduit 65 and on the other end is has two openings for coupling to the second ends 322, 342 of each of the first and second tubes 320, 340. Thus, the second portion 62 of the recirculation line 60, which includes the second conduit 65 and the second connector 66, converges from two pathways into a single pathway downstream of the second ends 322, 342 of the first and second tubes 320, 340 in a direction of the flow of the fluid through the recirculation line 60. Flare fittings, compression fittings, or the like may be used to couple the connector 66 to the second conduit 65 and to the first and second tubes 320, 340.

Because the first and second fluid flow passageways 325, 345 are formed from the separate first and second tubes 320, 340 and do not converge within the cavity 304 of the probe housing 301, the first and second tubes 320, 340 are coupled to the recirculation line 60 outside of or external to the probe housing 301. Specifically, each of the first and second tubes 320, 340 is separately coupled to the recirculation line 60 outside of the probe housing 301.

During use, the fluid is flowing through the recirculation loop 60 and hence also through the first and second tubes 320, 340 of the conductivity sensor 200. It should be noted that the entire volume of the fluid that flows through the recirculation loop 60 also flows through one of the first and second tubes 320, 340 of the conductivity sensor 200. The alternating current source (i.e., oscillator) is activated, which in turn causes the first toroid 335 to generate an electromagnetic field. The electromagnetic field induces an electrical current in the fluid that is flowing through the recirculation loop 60 and the first and second tubes 320, 240. The second toroid 355 detects the magnitude of the current in the fluid and then passes data indicative of the magnitude of the current in the fluid to the receiver 402 of the data analysis portion 400 of the conductivity sensor 200. The receiver 402 then sends this data to the controller 404, which processes the data to determine a value for the conductivity of the fluid. Specifically, in some embodiments the receiver 402 and/or controller 404 may process the data gathered by the second toroid 355 and convert it to a conductivity reading according to the equation σ=K*G, where σ is solution conductivity, K is a cell constant, and G is cell conductance.

The controller 404 may pass this information to the display device 403, which displays a numerical value of the conductivity. The display device 403 may be an LCD display or the like in various embodiments as desired, although the invention is not to be limited to a particular type of display device in all embodiments. In some embodiments, the display device 403 may be omitted and the conductivity values may simply be recorded in a memory device for later viewing by an end user or the conductivity values may be transmitted to the controller 50 of the system 100 so that the controller 50 can control activation of the various valves to adjust the concentration of the various chemicals in the fluid or aqueous solution or chemical solution as described herein above.

The conductivity sensor 200 can be used in both acids and bases. Some embodiments provide good results at room temperature from a conductivity of 100 μS to 100 mS, although other ranges are also possible. Some embodiments operate within a flow range of between 5 and 10 gpm, although other flow ranges can also be used. Some examples of conductivity sensor 200 operated with concentrations in SC1 from 1:2:100 to 1:2:35 show a linear increase in conductivity with increasing temperature. Some examples of conductivity sensor 200 operated with concentrations in SC2 from 1:1:100 to 1:1:35 show a linear increase in conductivity with increasing temperature.

While the foregoing description and drawings represent exemplary embodiments of the present disclosure, it will be understood that various additions, modifications and substitutions may be made therein without departing from the spirit and scope and range of equivalents of the accompanying claims. In particular, it will be clear to those skilled in the art that the present invention may be embodied in other forms, structures, arrangements, proportions, sizes, and with other elements, materials, and components, without departing from the spirit or essential characteristics thereof. In addition, numerous variations in the methods/processes described herein may be made within the scope of the present disclosure. One skilled in the art will further appreciate that the embodiments may be used with many modifications of structure, arrangement, proportions, sizes, materials, and components and otherwise, used in the practice of the disclosure, which are particularly adapted to specific environments and operative requirements without departing from the principles described herein. The presently disclosed embodiments are therefore to be considered in all respects as illustrative and not restrictive. The appended claims should be construed broadly, to include other variants and embodiments of the disclosure, which may be made by those skilled in the art without departing from the scope and range of equivalents. In addition, all combinations of any and all of the features described in the disclosure, in any combination, are part of the invention.

1. A conductivity sensor for measuring the conductivity of a fluid, the conductivity sensor comprising:
a probe portion comprising:
a probe housing extending from a first end to a second end along a longitudinal axis and comprising a cavity;
a first tube extending through the probe housing and comprising a first fluid flow passageway for conveying the fluid through the probe housing, the first tube having a first portion protruding from the first end of the probe housing, a second portion protruding from the second end of the probe housing, and a third portion located within the cavity of the probe housing;
a second tube extending through the probe housing and comprising a second fluid flow passageway for conveying the fluid through the probe housing, the second tube having a first portion protruding from the first end of the probe housing, a second portion protruding from the second end of the probe housing, and a third portion located within the cavity of the probe housing;
a first toroid located in the cavity of the probe housing and positioned around an outer surface of the third portion of the first tube; and
a second toroid located in the cavity of the probe housing and positioned around an outer surface of the third portion of the second tube.

2. The conductivity sensor according to claim 1 wherein the first and second fluid flow passageways do not converge within the cavity of the probe housing.

3. The conductivity sensor according to claim 1 wherein the first and second toroids are axially spaced apart within the cavity of the probe housing.

4. The conductivity sensor according to claim 1 wherein the first toroid is the only toroid coupled to the first tube and the second toroid is the only toroid coupled to the second tube.

5. The conductivity sensor according to claim 1 wherein the first and second tubes are formed from polytetrafluoroethylene (PTFE) or perfluoroalkoxy (PFA).

6. The conductivity sensor according to claim 1 wherein the first tube extends along a first axis from a first end to a second end and the second tube extends along a second axis from a first end to a second end, the first and second axes being parallel to each other and parallel to the longitudinal axis of the probe housing, and wherein the first and second ends of each of the first and second tubes are located outside of the cavity of the probe housing.

7. The conductivity sensor according to claim 6 wherein the first and second ends of the first and second tubes are flared.

8. The conductivity sensor according to claim 6 wherein each of the first and second tubes has a length measured from the first end to the second end, the length being between 7 inches and 9 inches.

9. The conductivity sensor according to claim 1 wherein the first toroid is a drive coil that is operably coupled to an alternating current source and the second toroid is a sense coil that is operably coupled to a receiver.

10. The conductivity sensor according to claim 9 further comprising a data analysis portion that is operably coupled to the probe portion, the data analysis portion comprising a second housing containing the alternating current source, the receiver, a display device, a power source, and a second controller that are operably coupled together, and wherein the second controller is configured to process measurement data received by the receiver from the second toroid and cause the display device to display a numerical conductivity value based on the measurement data.

11. The conductivity sensor according to claim 1 wherein the cavity of the probe housing is hermetically sealed to prevent fluid from flowing into the cavity except through the first and second fluid flow passageways of the first and second tubes.

12. A conductivity sensor for measuring the conductivity of a fluid, the conductivity sensor comprising:
a housing extending from a first end to a second end along a longitudinal axis and comprising a cavity;
a first tube extending through the housing and comprising a first fluid flow passageway for conveying the fluid through the housing;
a second tube extending through the housing and comprising a second fluid flow passageway for conveying the fluid through the housing;
a drive toroid located in the cavity of the housing and positioned around an outer surface of the first tube;
a sense toroid located in the cavity of the housing and positioned around an outer surface of the second tube; and
wherein the first and second fluid flow passageways do not converge within the cavity of the housing.

13. A system for processing flat articles comprising:
a process tank comprising a process chamber;
at least one fluid supply conduit operably coupled to the process tank for introducing a fluid into the process chamber;
a recirculation conduit fluidly coupled to the process chamber and configured to circulate the fluid;
a conductivity sensor operably coupled to the recirculation conduit and configured to measure conductivity of the fluid circulating through the recirculation conduit, the conductivity sensor comprising:
a housing extending from a first end to a second end along a longitudinal axis and comprising a cavity;
a first tube fluidly coupled to the recirculation line, the first tube extending through the housing and comprising a first fluid flow passageway for conveying the fluid through the housing;
a second tube fluidly coupled to the recirculation line, the second tube extending through the housing and comprising a second fluid flow passageway for conveying the fluid through the housing, wherein the first and second fluid flow passageways do not converge within the cavity of the housing;
a first toroid located in the cavity of the housing and positioned around an outer surface of the first tube; and
a second toroid located in the cavity of the housing and positioned around an outer surface of the second tube.

14. The system according to claim 13 wherein the first tube extends along a first axis from a first end to a second end and the second tube extends along a second axis from a first end to a second end, wherein the recirculation conduit comprises a first portion extending from the process tank to the first ends of the first and second tubes and a second portion extending from the process tank to the second ends of the first and second tubes, wherein the first portion of the recirculation conduit diverges from a single pathway to two pathways upstream of the first ends of the first and second tubes in a direction of a flow of the fluid, and wherein the second portion of the recirculation line converges from two pathways to a single pathway downstream of the second ends of the first and second tubes in a direction of the flow of the fluid.

15. The system according to claim 13 wherein the first tube has a first portion that protrudes from the first end of the housing to a first end of the first tube and a second portion that extends from the second end of the housing to a second end of the first tube, and wherein the second tube has a first portion that extends from the first end of the housing to a first end of the second tube and a second portion that extends from the second end of the housing to a second end of the second tube.

16. The system according to claim 13 wherein the cavity of the housing is hermetically sealed to prevent fluid from flowing into the cavity except through the first and second fluid flow passageways of the first and second tubes.

17. The system according to claim 13 wherein the first tube extends along a first axis from a first end of the first tube to a second end of the first tube and the second tube extends along a second axis from a first end of the second tube to a second end of the second tube, the first and second axes being parallel to each other and to the longitudinal axis of the housing, and wherein the first and second ends of each of the first and second tubes are located outside of the cavity of the probe housing.

18. The system according to claim 13 wherein the first and second ends of the first and second tubes are coupled to the recirculation conduit with a flare fitting.

19. The system according to claim 13 wherein the first toroid is configured as a drive coil and is the only toroid coupled to the first tube and the second toroid is configured as a sense coil and is the only toroid coupled to the second tube.

20. The system according to claim 13 wherein the first and second toroids are axially spaced apart within the cavity of the housing.

21.-23. (canceled)
